(19) United States
(12) Patent Application Publication
(10) Pub. No.: US 2026/0081574 A1
(43) Pub. Date: Mar. 19, 2026

(54) PROGRAMMABLE TRANSIMPEDANCE AMPLIFIER

(71) Applicant: EASII IC, Grenoble (FR)

(72) Inventors: Richard MORISSON, CORENC (FR); Jean-Paul GOGLIO, Pontcharra (FR)

(21) Appl. No.: 18/269,631

(22) PCT Filed: Dec. 23, 2021
(86) PCT No.: PCT/FR2021/052449

§ 371 Date: Jun. 26, 2023

(30) Foreign Application Priority Data
Dec. 28, 2020 (FR) FR20/14182

(51) Int. Cl. H03F 3/45; H03F 3/08; H03G 1/00; H03G 3/00; H03G 3/30

(52) U.S. Cl. CPC H03F 3/45475; H03F 3/087; H03G 1/0088; H03G 3/001; H03G 3/3084; H03F 2203/45514; H03F 2203/45526

(57) ABSTRACT

The present invention relates to a conversion device, or commonly called transimpedance amplifier, able to convert an input electric current (Id) from a current source such as a photonic sensor (D) into an output voltage (Vo) and comprising an integrated electronic circuit comprising, inter alia, a resistive component (Rf) of adjustable value and a capacitive component (Cf) of adjustable value. The invention also relates to a method for determining the values of the resistive component and of the capacitive component.

### TECHNICAL FIELD

The present disclosure relates to a conversion device capable of converting an input electric current originating from a photonic sensor into an output electric voltage and comprising an integrated electronic circuit comprising, inter alia, a resistive component with an adjustable value and a capacitive component with an adjustable value. The disclosure also relates to a method for determining the values of the resistive component and of the capacitive component.

### BACKGROUND

It is known to make a conversion device capable of converting an input electric current originating from a current source such as a photonic sensor into an output electric voltage and comprising an amplification component such as an operational amplifier, a resistive component and a capacitive component. This conversion device is commonly called a transimpedance amplifier. The amplification component, the resistive component and the capacitive component may be made in the same substrate of a semiconductor material and therefore form an integrated electronic circuit. The conversion device comprising this integrated electronic circuit may then be called an integrated transimpedance amplifier.

These arrangements are satisfactory in that it becomes possible to carry out, using a conversion device with reduced size, a conversion of the current signal originating from the photonic sensor or photodetector and often with a low amplitude, into a voltage signal that can be exploited.

Nonetheless, the values of some parameters of the photodetector may vary due to external factors such as an external temperature or else due to internal factors such as ageing of the photodetector, for example, consequently resulting in erroneous operation of the conversion device.

The present disclosure aims at solving all or part of the aforementioned drawbacks mentioned above.

The technical problem at the origin of the disclosure consists in particular in providing a conversion device with a reduced size capable of converting an input electric current originating from a photonic sensor into an output electric voltage which can overcome variations in the values of some parameters of the photodetector and which has a simple and economical structure.

### BRIEF SUMMARY

To this end, the present disclosure relates to an integrated electronic circuit comprising:
an amplification component comprising at least one input port and one output port, the amplification component being characterized by a bias current value, the bias current value being modifiable in situ without dismounting the amplification component off the integrated electronic circuit;
a resistive component having a first terminal electrically connected to the input port of the amplification component and a second terminal electrically connected to the output port of the amplification component, the resistive component having a resistance value considered between its first terminal and its second terminal and conferring an ability to modify said resistance value in situ without dismounting the resistive component off the integrated electronic circuit;
a capacitive component having a first terminal electrically connected to the input port of the amplification component and a second terminal electrically connected to the output port of the amplification component, the resistive component and the capacitive component being electrically arranged in parallel with respect to each other, the capacitive component having a capacitance value between its first terminal and its second terminal and conferring an ability to modify said capacitance value in situ without dismounting the capacitive component off the integrated electronic circuit; and
a digital adjustment control capable of determining the following three values: the modifiable resistance value of the resistive component, the modifiable capacitance value of the capacitive component and the modifiable bias current value of the amplification component,
the digital adjustment control comprising:
   a component for detecting a limit value of an output signal at the output port of the amplification component;
   a calculation unit connected to the detection component and arranged to adjust the value of the resistance of the resistive component and the value of the capacitance of the capacitive component so as to adjust a value of a characteristic relating to the amplification component when the limit value of the output signal is detected by the detection component,
the digital adjustment command being applied through a communication bus connecting the calculation unit and a control circuit of a resistive branch switch and between the calculation unit and a control circuit of a capacitive branch switch;
said integrated electronic circuit comprising at least one first terminal connected to the input port of the amplification component, said first terminal being connected to a photonic sensor supplying an input electric current,
the photonic sensor comprising at least one photodiode.

In particular, the amplification component may refer to an operational amplifier.

The operational amplifier may have a single input, in other words have a single input port, or a differential input, in other words have two input ports.

Advantageously, the resistive component enables an adjustment of a gain of the amplification component, in particular of the operational amplifier.

Advantageously, thanks to their respective abilities to adjust the resistance value and the capacitance value, the resistive component and the capacitive component allow dispensing with the use of an adjustment component external to the integrated electronic circuit described herein.

Advantageously, the ability to modify the bias current value enables an adjustment of a noise of the amplification component.

Advantageously, the ability to modify the bias current value enables an adjustment of the consumption of the amplification component.

The integrated electronic circuit may further have one or more of the following features, considered alone or in combination.

The amplification component comprises a plurality of differential operational amplifiers connected in cascade one after another, each differential operational amplifier of the plurality of differential operational amplifiers comprising a first input terminal and a second input terminal and a first output terminal and a second output terminal, so that:
each first output terminal of a differential operational amplifier of the plurality of differential operational amplifiers is connected to the first input terminal of the next differential operational amplifier, and
each second output terminal of a differential operational amplifier of the plurality of differential operational amplifiers is connected to the second input terminal of the next differential operational amplifier.

For example, the detection component may be a circuit for detecting a peak-to-peak voltage value.

For example, the calculation unit may be a microcontroller connected to the detection circuit and configured to adjust the resistance value of the resistive component and/or the capacitance value of the capacitive component.

For example, the characteristic relating to the amplification component may be the gain of the amplification component, in particular of the operational amplifier.

The output signal may be an electric voltage, for example which will be injected into a circuit for converting an analog signal into a digital signal, also called an analog-to-digital converter.

The limit value of the output signal may refer to a peak-to-peak value of the output voltage having a predefined value, for example 1.1 V, the limit value being defined so as to avoid a saturation of the analog signal in the analog-to-digital converter.

According to one possibility, the resistive component comprises a plurality of resistive circuit branches, each resistive circuit branch comprising a partial resistive component, a resistive branch switch, and a control circuit controlling the resistive branch switch.

The capacitive component may comprise a plurality of capacitive circuit branches, each capacitive circuit branch comprising a partial capacitive component, a capacitive branch switch, and a control circuit controlling the capacitive branch switch.

According to one possibility, each resistive branch switch and each capacitive branch switch is a transistor made of a semiconductor material, for example using a CMOS type technology.

According to one possibility, each resistive branch switch and each capacitive branch switch is an NMOS type, PMOS type or dual MOS type transistor.

According to one embodiment, the calculation unit adjusts the resistance value of the resistive component by controlling the opening and closure of each resistive branch switch in each resistive circuit branch.

According to one embodiment, the calculation unit adjusts the value of the capacitance of the capacitive component by controlling the opening and closure of each capacitive branch switch in each capacitive circuit branch.

Advantageously, the partial resistive component has a resistance value substantially higher than a conduction resistance of the switch so as to guarantee stability of a gain value of the amplification component despite temperature variations. For example, the resistance value of the partial resistive component may be more than 20 times higher than the conduction resistance of the switch.

The resistive component and the capacitive component may be integrated into a substrate made of a semiconductor material.

According to one possibility, the semiconductor material may be raw silicon or Silicon-on-Insulator or SOI.

The resistive component and the capacitive component may be made using a CMOS or BiCMOS type technology.

The present disclosure also relates to a conversion device capable of converting an input electric current into an output electric voltage, comprising a photonic sensor and the described integrated electronic circuit, said photonic sensor being connected to said integrated circuit and said electric current input being supplied by the photonic sensor.

Advantageously, the fact that the bias current value is adjustable, the fact that the resistive component has an ability to modify the resistance value and the fact that the capacitive component has an ability to modify the capacitance value, allow using the conversion device with a photodiode, or photonic diode, having a junction capacitance varying over a wide range of junction capacitances, for example between 1 pF and 20 pF.

Advantageously, the ability to modify the bias current value enables an adjustment of a bandwidth of the amplification component according to a capacitance value of the photodiode, the value resistance of the resistive component and the capacitance value of the capacitive component.

According to one possibility, the photonic sensor may be a phototransistor, a PIN type photodiode, or an avalanche type photodiode.

According to one possibility, the conversion device comprises a digitization component and the output port of the amplification component is electrically connected to the digitization component.

For example, the digitization component may be an analog-to-digital converter capable of digitizing the electrical output voltage present at the output of the conversion device.

The output port of the amplification component may be directly connected to the digitization component.

According to one alternative, the output port of the amplification component may be connected to an electronic filter which is connected to the digitization component, the electronic filter being intended to avoid aliasing of the output signal of the amplification component, in other words to restrict the bandwidth of the output signal in order to comply with a sampling theorem such as the Nyquist-Shannon theorem.

The disclosure also relates to a method for determining a resistance value present between a first terminal and a second terminal of a resistive component, in which method the resistive component forms an integral part of the described integrated electronic circuit and confers an ability to modify said resistance value in situ without dismounting the resistive component off the integrated electronic circuit, in which method the digital adjustment control which belongs to the integrated electronic circuit comprises:
a component for detecting a limit value of an output signal at the output port of the amplification component which belongs to the integrated electronic circuit;
a calculation unit connected to the detection component and arranged to adjust the value of the resistance of the resistive component and the value of the capacitance of the capacitive component which belongs to the integrated electronic circuit so as to adjust a value of a characteristic relating to the amplification component when the limit value of the output signal is detected by the detection component;
the method comprising the following steps:
   detecting, by the detection component, the limit value of the output signal at the output port of the amplification component;
   modifying an output value of the detection component based on the limit value of the output signal at the output port of the amplification component;
   transmitting the output value of the detection component to the calculation unit.

According to one possibility, the resistive component of the integrated electronic circuit comprises a plurality of resistive circuit branches, each resistive circuit branch comprising a partial resistive component, a resistive branch switch, and a control circuit controlling the resistive branch switch,
the method comprising the following steps:
   transmitting, by the calculation unit, a control signal of the resistive branch switch controlled by the control circuit of the resistive branch switch;
   actuating the resistive branch switch based on the control signal sent by the calculation unit; and
   modifying the value of the resistance of the resistive component according to the actuated resistive branch switch.

The disclosure also relates to a method for determining a capacitance value present between a first terminal and a second terminal of a capacitive component, in which method the capacitive component forms an integral part of a described integrated electronic circuit and confers an ability to modify said capacitance value in situ without dismounting the capacitive component off the integrated electronic circuit, in which method the capacitive component comprises a plurality of capacitive circuit branches, each capacitive circuit branch comprising a partial capacitive component, a capacitive branch switch, and a control circuit controlling the capacitive branch switch,
the method comprising the following steps:
   determining, by a calculation unit, a value of a bandwidth relating to the integrated electronic circuit;
   transmitting, by the calculation unit, a control signal of the capacitive branch switch controlled by the control circuit of the capacitive branch switch based on the value of the determined bandwidth;
   actuating the capacitive branch switch based on the control signal sent by the calculation unit; and
   modifying the capacitance value associated with the capacitive component according to the actuated capacitive branch switch.

According to one implementation, the determination of the value of the bandwidth relating to the integrated electronic circuit is done according to the value of the resistance of the resistive component, the capacitance of the photonic sensor at the input and a input capacitance of the amplification component.

### BRIEF DESCRIPTION OF THE DRAWINGS

The disclosure will be better understood from the detailed description which is set out hereinbelow with reference to the appended drawings wherein:

FIG. 1 is a schematic representation of an electrical circuit of a first embodiment of a conversion device capable of converting an input electric current into an output electric voltage comprising an integrated circuit comprising an amplification component, a resistive component having a variable resistance value and a capacitive component having a variable value capacitance.

FIG. 2 is a schematic representation of an electrical circuit of a second embodiment of the conversion device of FIG. 1 comprising several amplification components having differential inputs.

FIG. 3 is a schematic representation of an electrical circuit of a third embodiment of the conversion device of FIG. 1 comprising an amplification component and a transistor intended to amplify an input signal of said conversion device.

FIG. 4 is a flowchart showing different steps executed during the completion of a method for determining a resistance value of the resistive component comprised in the integrated circuit of the conversion device of FIG. 1.

FIG. 5 is a flowchart showing different steps executed during the completion of a method for determining a capacitance value of the capacitive component comprised in the integrated circuit of the conversion device of FIG. 1.

### DETAILED DESCRIPTION

In the following detailed description of the figures defined hereinabove, the same elements or the elements filling identical functions may keep the same references so as to simplify understanding of the disclosure.

### Integrated Electronic Circuit

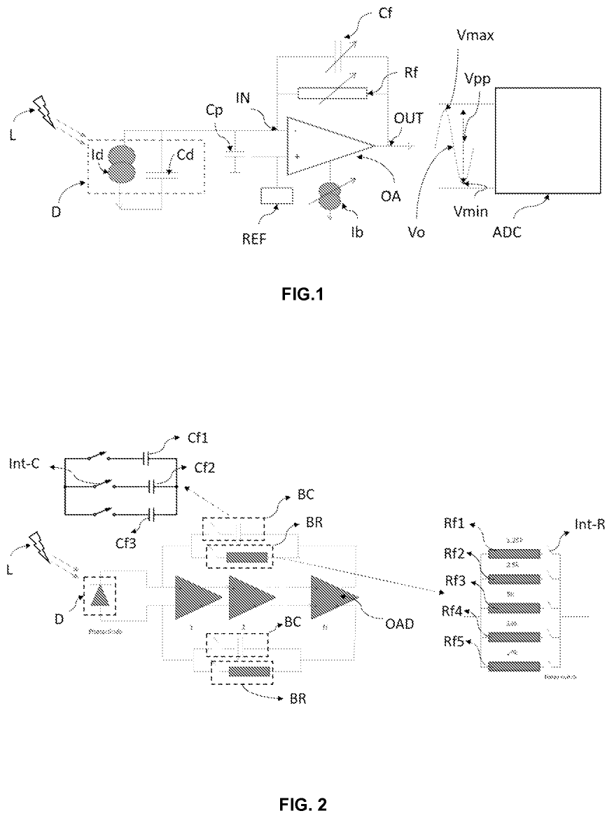

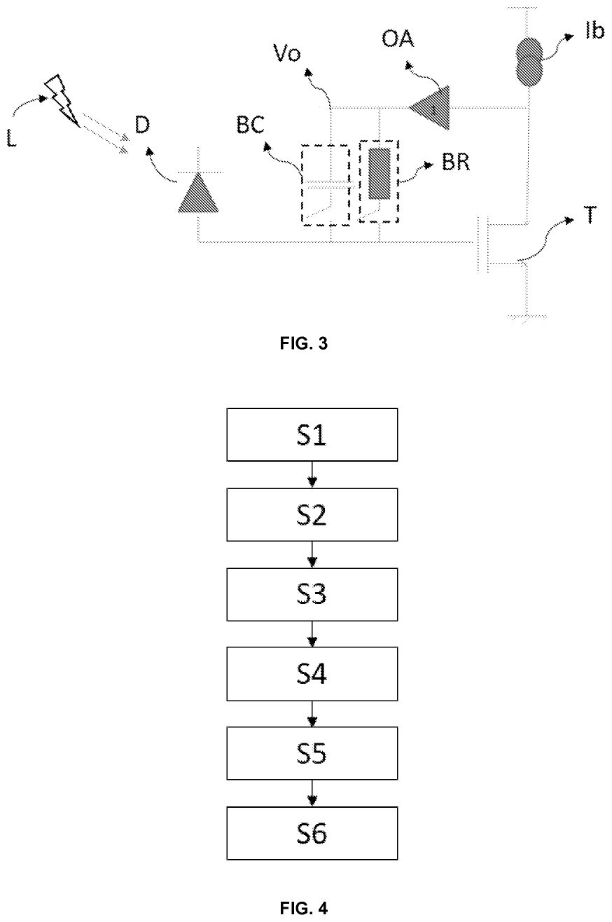

The disclosure relates first of all to an integrated electronic circuit comprising an amplification component OA comprising at least one input port IN and one output port OUT, the amplification component OA being characterized by a bias current value Ib, the bias current value Ib being modifiable in situ without dismounting the amplification component OA off the integrated electronic circuit. In particular, the amplification component OA may refer to an operational amplifier and said operational amplifier may have one single input, in other words have one single input port as is the case in FIGS. 1 and 3 or a differential input, in other words have two inlet ports as is the case in FIG. 2.

According to an embodiment shown in FIG. 2, the amplification component OA comprises a plurality of differential operational amplifiers mounted in cascade one after another, each differential operational amplifier OAD1, OAD3 of the plurality of differential operational amplifiers comprising a first input terminal E1 and a second input terminal E2 and a first output terminal O1 and a second output terminal O2, so that:
each first output terminal O1 of a differential operational amplifier of the plurality of differential operational amplifiers is connected to the first input terminal E1 of the next differential operational amplifier, and
each second output terminal O2 of a differential operational amplifier of the plurality of differential operational amplifiers is connected to the second input terminal E2 of the next differential operational amplifier.

Advantageously, the plurality of differential operational amplifiers mounted in cascade allows varying the parameters of the circuit in order to obtain predefined bandwidth and noise values.

The integrated electronic circuit also comprises a resistive component Rf having a first terminal electrically connected to the input port IN of the amplification component OA and a second terminal electrically connected to the output port OUT of the amplification component OA, the resistive component Rf having a resistance value considered between its first terminal and its second terminal and conferring an ability to modify said resistance value in situ without dismounting the resistive component off the integrated electronic circuit.

Advantageously, the resistive component Rf enables an adjustment of a gain of the amplification component, in particular of the operational amplifier.

The integrated electronic circuit also comprises a capacitive component Cf having a first terminal electrically connected to the input port IN of the amplification component OA and a second terminal electrically connected to the output port OUT of the amplification component OA, the resistive component Rf and the capacitive component Cf being electrically arranged in parallel with respect to each other, the capacitive component Cf having a capacitance value between its first terminal and its second terminal and conferring an ability to modify said capacitance value in situ without dismounting the capacitive component Cf off the integrated electronic circuit.

Advantageously, thanks to their respective abilities to be adjust the resistance value and the capacitance value, the resistive component Rf and the capacitive component Cf allow dispensing with the use of an adjustment component external to the integrated electronic circuit described herein.

The resistive component Rf and the capacitive component Cf are integrated into a substrate made of a semiconductor material.

According to one possibility, the semiconductor material may be raw silicon or silicon-on-Insulator or SOI.

The resistive component Rf and the capacitive component Cf are made using a CMOS or BiCMOS type technology.

The integrated electronic circuit comprises at least one first terminal connected to the input port IN of the amplification component, said first terminal being connected to a photonic sensor D supplying an input electric current Id and the photonic sensor D comprising at least one photodiode.

The integrated electronic circuit also comprises a digital adjustment control capable of determining the following three values: the modifiable resistance value of the resistive component Rf, the modifiable capacitance value of the capacitive component Cf and the modifiable bias current value Ib of the amplification component OA.

Advantageously, the ability to modify the bias current value Ib enables an adjustment of a noise of the amplification component AO.

Advantageously, the ability to modify the bias current value Ib enables an adjustment of the consumption of the amplification component OA.

The digital adjustment control comprises a component for detecting a limit value Vpp of an output signal Vo at the output port OUT of the amplification component OA, the detection component possibly being for example a circuit for detecting a peak-to-peak voltage value.

The output signal Vo may be an electric voltage, for example which will be injected into a circuit ADC for converting an analog signal into a digital signal, also called digitization circuit or analog-to-digital converter.

The digital adjustment control also comprises a calculation unit connected to the detection component and arranged to adjust the value of the resistance of the resistive component Rf and the value of the capacitance of the capacitive component Cf so as to adjust a value of a characteristic relating to the amplification component OA, for example the gain of the amplification component OA, in particular of the operational amplifier, when the limit value of the output signal Vo is detected by the detection component.

For example, the calculation unit may be a microcontroller connected to the detection circuit and configured to adjust the value of the resistance of the resistive component Rf and/or the value of the capacitance of the capacitive component Cf.

The limit value Vpp of the output signal may refer to a peak-to-peak value of the output voltage having a predefined value, for example 1.1 V, the limit value being defined so as to avoid saturation of the analog signal in the analog-to-digital converter.

In the described integrated electronic circuit, the resistive component Rf comprises a plurality of resistive circuit branches BR, each resistive circuit branch BR comprising a partial resistive component Rfi (Rf1, Rf2, . . . ,

Rf5) shown in FIG. 2, a resistive branch switch Int-R, and a control circuit controlling the resistive branch switch Int-R.

Advantageously, the partial resistive component Rfi has a resistance value substantially higher than a conduction resistance of the resistive branch switch Int-R so as to guarantee stability of a gain value of the amplification component OA despite the temperature variations.

For example, the value of the resistance of the partial resistive component Rfi may be more than 20 times higher than the conduction resistance of the resistive branch switch Int-R.

In the described integrated electronic circuit, the capacitive component Cf comprises a plurality of capacitive circuit branches BC, each capacitive circuit branch BC comprising a partial capacitive component Cfi (Cf 1, Cf2, Cf3) shown in FIG. 2, a capacitive branch switch Int-C, and a control circuit controlling the capacitive branch switch Int-C.

According to one possibility, each resistive branch switch Int-R and each capacitive branch switch Int-C is a transistor made of a semiconductor material, for example based on a CMOS type technology.

According to one possibility, each resistive branch switch Int-R and each capacitive branch switch Int-C is an NMOS type, PMOS type or dual MOS type transistor.

According to one embodiment, the calculation unit adjusts the value of the resistance of the resistive component Rf by controlling the opening and closure of each resistive branch switch Int-R in each resistive circuit branch BR.

According to one embodiment, the calculation unit adjusts the value of the capacitance of the capacitive component Cf by controlling the opening and closure of each capacitive branch switch Int-C in each capacitive circuit branch BC.

The digital adjustment command is applied through a communication bus, for example a low-speed communication bus of the 12C or SPI type, connecting the calculation unit and the control circuit of the resistive branch switch Int-R and between the calculation unit and the control circuit of the capacitive branch switch Int-C.

### Conversion Device: Composition

The disclosure also relates to a conversion device capable of converting the input electric current Id into an output electric voltage Vo, or commonly referred to as a transimpedance amplifier, comprising a photonic sensor or photodetector D and the integrated electronic circuit described before, said photon sensor D being connected to said integrated circuit and said input electric current Id being supplied by the photon sensor D.

The photonic sensor D may comprise at least one photodiode.

According to one possibility, the photon sensor D may be a phototransistor, a PIN type photodiode, or an avalanche type photodiode.

The conversion device or transimpedance amplifier, one embodiment of which is shown in FIG. 1, is remarkable in that it integrates the integrated circuit described before, in other words it is possible to modify the value of the resistance of the resistive component Rf as well the value of the capacitance of the capacitive component Cf and that of the bias current Ib of the amplification component OA or operational amplifier in order to modify or adjust some characteristics of the transimpedance amplifier such as a gain, a bandwidth, a power consumption or an operating noise.

Advantageously, the fact that the bias current value Ib is adjustable, the fact that the resistive component Rf has an ability to modify the resistance value and the fact that the capacitive component Cf has an ability to modify the capacitance value, allow using the conversion device with a photodiode, or photonic diode, having a junction capacitance Cd varying within a wide range of junction capacitances, for example between 1 pF and 20 pF.

Thus, a modification of the value of the resistance of the resistive component Rf and a modification of the value of the capacitance of the capacitive component Cf could compensate for a variation in the junction capacitance Cd of the photodiode due to external factors such as a variation in a temperature of a room for example or internal factors such as aging of the photodiode for example.

The value of the resistance of the resistive component Rf is related to the output electric voltage Vo and to the input electric current Id by the equation [Math 1].

$$R f = \frac{V max - V min}{2. Id} \qquad [ Math 1 ]$$

The quantities Vmax and Vmin are shown in FIG. 1 and designate respectively a maximum value and a minimum value of the output voltage Vo of the transimpedance amplifier. Thus, if the values of Vmax, Vmin and Id are known, it is possible to calculate the value of the resistance of the resistive component Rf according to [Math 1].

Moreover and advantageously, the fact that the bias current value Ib is adjustable, the fact that the resistive component Rf has an ability to modify the resistance value and the fact that the capacitive component Cf has an ability to modify the capacitance value, allow using the conversion device with several types of photodiodes having different junction capacitance values Cd.

Advantageously, the ability to modify the bias current value Ib enables an adjustment of a bandwidth of the amplification component OA according to a capacitance value of the photodiode Cd, of the resistance value of the resistive component Rf and the capacitance value of the capacitive component Cf.

The value of the bias current Ib is related to the junction capacitance of the photodiode Cd, to an input capacitance Cp of the amplification component OA, to a bandwidth fc of the amplification component OA as well as to a constant VT according to the equation [Math 2].

$$Ib = {fc}^{2} . 4 {π}^{2} . Cp . ( Cd + Cp ) . V T \qquad [ Math 2 ]$$

Thus, by setting an operating value of the bandwidth fc of the amplification component and having knowledge of the values of the junction capacitance Cd of the photodiode and of the input capacitance Cp of the amplification component OA, it is possible to determine the value of the bias current Ib.

The input capacitance Cp of the amplification component OA may entirely or partially consist of a parasitic capacitance at the input of the amplification component OA.

The value of the capacitance of the capacitive component Cf relates to the junction capacitance Cd of the photodiode, to the input capacitance Cp of the amplification component, to the value of the resistance of the resistive component Rf as well as to a product of the bandwidth of the amplification component by a gain of the amplification component more commonly called the gain-band product GBW of the amplification component according to the equation [Math 3].

$$Cf \geq \sqrt{\frac{Cd + Cp}{π . G B W . Rf}} \qquad [ Math 3 ]$$

Knowing thus the value of the resistance of the resistive component Rf, that of the junction capacitance Cd of the photodiode, the input capacitance Cp of the amplification component OA and by setting a value of the desired gain-band product GBW, it is possible to calculate the value of the capacitance of the capacitive component Cf.

The equation [Math 3] may also represent a sizing criterion of the conversion device which should be met in order to guarantee stability of the described conversion device during operation thereof.

The conversion device may comprise a digitization component ADC and the output port OUT of the amplification component OA may be electrically connected to the digitization component ADC.

For example, the digitization component ADC may be an analog-to-digital converter capable of digitizing the output electric voltage Vo present at the output of the conversion device OA.

The output port OUT of the amplification component OA may be directly connected to the digitization component ADC.

According to one alternative, the output port OUT of the amplification component OA may be connected to an electronic filter which is connected to the digitization component ADC, the electronic filter being intended to avoid aliasing of the output signal of the amplification component, in other words to restrict the bandwidth of the output signal in order to comply with a sampling theorem such as the Nyquist-Shannon theorem.

### Conversion Device: Operation

According to a first embodiment shown in FIG. 1, a radiation L is detected by the photodetector D which converts the radiation L into the electric current Id.

This electric current Id is injected into the conversion device comprising the amplification component OA as well as the described integrated circuit inter alia.

The conversion device then converts the input electric current Id into the output voltage Vo. The output voltage Vo, which may be sinusoidal and which has the peak-to-peak value Vpp, the minimum value Vmin and the maximum value Vmax, is intended for use in a given application.

The output voltage Vo is then injected, directly or through an anti-aliasing filter, into the digitization device ADC or analog-to-digital converter to be converted into a digital signal intended to be exploited.

During the operation of the described conversion device, factors internal or external to the conversion device could for example modify the value of the junction diode Cd of the photodiode, which risks destabilizing the conversion device for example. In order to avoid this risk of destabilization or else of erroneous operation of said conversion device, it is possible to program or adjust the resistance values of the resistive component Rf, of the capacitance of the capacitive component Cf and of the bias current Ib of the amplification component OA.

The values of the resistance of the resistive component Rf, of the capacitance of the capacitive component Cf and of the bias current Ib of the amplification component OA may be modified together or each separately according to the needs of the intended application.

The value of the resistance of the resistive component Rf is determined and modified according to a method for determining a resistance value described hereinafter.

Similarly, the value of the capacitance of the resistive component Cf is determined and modified according to a method for determining a capacitance value described hereinafter.

It is possible to make the conversion device having the same operation as that one described before according to a second embodiment shown in FIG. 2, where the conversion device comprises a plurality of differential amplification components OAD as well as the described integrated circuit inter alia.

It is also possible to make the conversion device having the same operation as that one described before according to a third embodiment shown in FIG. 3, where the input electric current Id is injected into a transistor T in order to be amplified before being injected into the amplification component OA and be converted by said amplification component OA into the output voltage Vo which will be digitized by the digitization device ADC.

### Method for Determining a Resistance Value

The disclosure also relates to the method for determining a resistance value present between the first terminal and the second terminal of the resistive component Rf, in which method the resistive component Rf forms an integral part of the integrated electronic circuit described before and confers an ability to modify said resistance value in situ without dismounting the resistive component Rf off the integrated electronic circuit, in which method the digital adjustment control which belongs to the integrated electronic circuit comprises:
the component for detecting a limit value of an output signal Vo at the output port OUT of the amplification component OA which belongs to the integrated electronic circuit;
the aforementioned calculation unit connected to the detection component and arranged to adjust the value of the resistance of the resistive component Rf and the value of the capacitance of the capacitive component Cf which belongs to the integrated electronic circuit so as to adjust the value of the characteristic relating to the amplification component OA when the limit value of the output signal Vo is detected by the detection component;
the method comprising the following steps shown in FIG. 4:
   detecting S1, by the detection component, the limit value of the output signal Vo at the output port OUT of the amplification component OA;
   modifying S2 an output value of the detection component based on the limit value Vpp of the output signal Vo at the output port OUT of the amplification component OA;
   transmitting S3 the output value of the detection component to the calculation unit.
   transmitting S4, by the calculation unit, the control signal of the resistive branch switch Int-R controlled by the control circuit of the resistive branch switch BR;
   actuating S5 the resistive branch switch Int-R based on the control signal sent by the calculation unit; and
   modifying S6 the value of the resistance of the resistive component Rf according to the actuated resistive branch switch Int-R.

According to one possibility, a single resistive branch switch Int-R is actuated and in this case the value of the resistance of the resistive component Rf is given by a resistance value of a single partial resistive component Rfi.

According to another possibility, several switches of resistive branches Int-R are actuated at the same time and in this case the value of the resistance of the resistive component Rf is given by a resistance value resulting from the combination of several partial resistive components, for example the resistance value resulting from the parallel setting two partial resistive components.

### Method for Determining a Capacitance Value

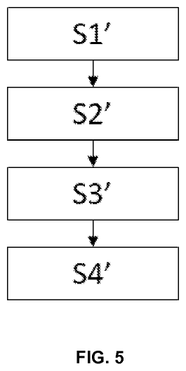

The disclosure further relates to the method for determining a capacitance value present between the first terminal and the second terminal of the capacitive component Cf, in which method the capacitive component Cf forms an integral part of the integrated electronic circuit described before and confers an ability to modify said capacitance value in situ without dismounting the capacitive component Cf off the integrated electronic circuit, in which method the capacitive component Cf comprises a plurality of capacitive circuit branches BC, each capacitive circuit branch BC comprising a partial capacitive component Cfi, a capacitive branch switch Int-C, and a control circuit controlling the capacitive branch switch Int-C, the method comprising the following steps shown in FIG. 5:
determining S1′, by the aforementioned calculation unit, a value of a bandwidth relating to the integrated electronic circuit;
transmitting S2′, by the calculation unit, the control signal of the capacitive branch switch Int-C controlled by the control circuit of the capacitive branch switch Int-C based on the determined value of the band bandwidth;
actuating S3′ the capacitive branch switch Int-C based on the control signal sent by the calculation unit; and
modifying S4′ the capacitance value associated with the capacitive component Cf according to the actuated capacitive branch switch Int-C.

According to one implementation, the determination of the value of the bandwidth relating to the integrated electronic circuit is done according to the value of the resistance of the resistive component Rf, of the capacitance of the photonic sensor D at the input and of the input capacitance of the amplification component Cp.

According to one possibility, one single capacitive branch switch Int-C is actuated and in this case the value of the capacitance of the capacitive component Cf is given by a capacitance value of one single partial capacitive component Cfi.

According to another possibility, several capacitive branch switches Int-C are actuated at the same time and in this case the value of the capacitance of the capacitive component Cf is given by a capacitance value resulting from the combination of several partial capacitive components, for example the capacitance value resulting from the parallel setting of two partial capacitive components.

Although the disclosure has been described with reference to particular embodiments, it is obvious that it is in no way limited thereto and that it encompasses all technical equivalents of the described means as well as their combinations if these fall within the scope of the disclosure.

1. An integrated electronic circuit comprising:
an amplification component comprising at least one input port and one output port, the amplification component being characterized by a bias current value, the bias current value being modifiable in situ without dismounting the amplification component off the integrated electronic circuit;
a resistive component having a first terminal electrically connected to the input port of the amplification component and a second terminal electrically connected to the output port of the amplification component, the resistive component having a resistance value considered between its first terminal and its second terminal and conferring an ability to modify said resistance value in situ without dismounting the resistive component off the integrated electronic circuit;
a capacitive component having a first terminal electrically connected to the input port of the amplification component and a second terminal electrically connected to the output port of the amplification component, the resistive component and the capacitive component being electrically arranged in parallel with respect to each other, the capacitive component having a capacitance value between its first terminal and its second terminal and conferring an ability to modify said capacitance value in situ without dismounting the capacitive component off the integrated electronic circuit; and
a digital adjustment control capable of determining the following three values: the modifiable resistance value of the resistive component, the modifiable capacitance value of the capacitive component and the modifiable bias current value of the amplification component,
the digital adjustment control comprising:
a component for detecting a limit value of an output signal at the output port of the amplification component;
a calculation unit connected to the detection component and arranged to adjust the value of the resistance of the resistive component and the value of the capacitance of the capacitive component so as to adjust a value of a characteristic relating to the amplification component when the limit value of the output signal is detected by the detection component,
the digital adjustment command being applied through a communication bus connecting the calculation unit and a control circuit of a resistive branch switch and between the calculation unit and a control circuit of a capacitive branch switch;
said integrated electronic circuit comprising at least one first terminal connected to the input port of the amplification component, said first terminal being connected to a photonic sensor supplying an input electric current,
the photonic sensor comprising at least one photodiode.

2. The electronic circuit according to claim 1, wherein the amplification component comprises a plurality of differential operational amplifiers connected in cascade one after another, each differential operational amplifier of the plurality of differential operational amplifiers comprising a first input terminal and a second input terminal and a first output terminal and a second output terminal, so that
each first output terminal of a differential operational amplifier of the plurality of differential operational amplifiers is connected to the first input terminal of the next differential operational amplifier, and
each second output terminal of a differential operational amplifier of the plurality of differential operational amplifiers is connected to the second input terminal of the next differential operational amplifier.

3. The integrated electronic circuit according to claim 1, wherein the resistive component comprises a plurality of resistive circuit branches, each resistive circuit branch comprising a partial resistive component, a resistive branch switch, and a control circuit controlling the resistive branch switch.

4. The integrated electronic circuit according to claim 1, wherein the capacitive component comprises a plurality of capacitive circuit branches, each capacitive circuit branch comprising a partial capacitive component, a capacitive branch switch, and a control circuit controlling the capacitive branch switch.

5. The integrated electronic circuit according to claim 1, wherein the resistive component and the capacitive component are integrated into a substrate made of a semiconductor material.

6. The integrated electronic circuit according to claim 1, wherein the resistive component and the capacitive component are made using a CMOS or BiCMOS type technology.

7. A conversion device adapted to convert an input electric current into an output electric voltage, comprising a photonic sensor and an integrated electronic circuit according to claim 1, said photonic sensor being connected to said integrated circuit and said input electric current being supplied by the photonic sensor.

8. The conversion device according to claim 7, wherein the conversion device comprises a digitization component and wherein the output port of the amplification component is electrically connected to the digitization component.

9. A method for determining a resistance value present between a first terminal and a second terminal of a resistive component, in which method the resistive component forms an integral part of an integrated electronic circuit according to claim 1 and confers an ability to modify said resistance value in situ without dismounting the resistive component off the integrated electronic circuit, in which method the digital adjustment control which belongs to the integrated electronic circuit comprises:
a component for detecting a limit value of an output signal at the output port of the amplification component which belongs to the integrated electronic circuit;
a calculation unit connected to the detection component and arranged to adjust the value of the resistance of the resistive component and the value of the capacitance of the capacitive component which belongs to the integrated electronic circuit so as to adjust a value of a characteristic relating to the amplification component when the limit value of the output signal is detected by the detection component;
the method comprising the following steps:
detecting, by the detection component, the limit value of the output signal at the output port of the amplification component;
modifying an output value of the detection component based on the limit value of the output signal at the output port of the amplification component;
transmitting the output value of the detection component to the calculation unit.

10. The method for determining a resistance value according to claim 9, wherein the resistive component of the integrated electronic circuit comprises a plurality of resistive circuit branches, each resistive circuit branch comprising a partial resistive component, a resistive branch switch, and a control circuit controlling the resistive branch switch,
the method comprising the following steps:
transmitting, by the calculation unit, a control signal of the resistive branch switch controlled by the control circuit of the resistive branch switch;
actuating the resistive branch switch based on the control signal sent by the calculation unit; and
modifying the value of the resistance of the resistive component according to the actuated resistive branch switch.

11. A method for determining a capacitance value present between a first terminal and a second terminal of a capacitive component, in which method the capacitive component forms an integral part of an integrated electronic circuit according to claim 1 and confers an ability to modify said capacitance value in situ without dismounting the capacitive component off the integrated electronic circuit, in which method the capacitive component comprises a plurality of capacitive circuit branches, each capacitive circuit branch comprising a partial capacitive component, a capacitive branch switch, and a control circuit controlling the capacitive branch switch,
the method comprising the following steps:
determining, by a calculation unit, a value of a bandwidth relating to the integrated electronic circuit;
transmitting, by the calculation unit, a control signal of the capacitive branch switch controlled by the control circuit of the capacitive branch switch based on the value of the determined bandwidth;
actuating the capacitive branch switch based on the control signal sent by the calculation unit; and
modifying the capacitance value associated with the capacitive component according to the actuated capacitive branch switch.
